(19) United States
(12) Patent Application Publication
(10) Pub. No.: US 2009/0029564 A1
(43) Pub. Date: Jan. 29, 2009

(54) PLASMA TREATMENT APPARATUS AND PLASMA TREATMENT METHOD

(75) Inventors: Jun Yamashita, Hyogo (JP); Toshio Nakanishi, Hyogo (JP); Tatsuo Nishita, Hyogo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/916,166

(22) PCT Filed: May 30, 2006
(86) PCT No.: PCT/JP2006/310746

§ 371 Date: Jan. 4, 2008

(30) Foreign Application Priority Data
May 31, 2005 (JP) 2005-158246

(51) Int. Cl. H01L 21/31; C23C 16/00; H05H 1/24

(52) U.S. Cl. 438/788; 118/728; 427/579; 257/E21.278

(57) ABSTRACT

In a plasma oxidation treatment apparatus 100, dual plate structure 60 is arranged above a susceptor 2. An upper plate 61 and a lower plate 62 are made of a dielectric material such as quartz, separately arranged in parallel at a prescribed interval, for instance an interval of 5 mm, and have a plurality of through holes 61a, 62a. The two plates are arranged one over another by shifting the positions so that the through hole 62a of the lower plate 62 and the through hole 61a of the upper plate 61 are not overlapped.

### FIELD OF THE INVENTION

The present invention relates to a plasma processing apparatus and a plasma processing method for performing a process on a target substrate such as a semiconductor substrate or the like by using a plasma to form an oxide film, a nitride film, an oxynitride film or the like on a surface thereof.

### BACKGROUND OF THE INVENTION

In a manufacturing process of various semiconductor devices, a silicon oxidation process or the like is performed in order to form an insulating film or the like. A silicon oxide film is extremely stable and serves as a protective film against the external environment. Therefore, a technique for forming a silicon oxide film is very important in the manufacture of semiconductor devices. Recently, along with the trend for miniaturization of semiconductor devices, there is required a technique for forming a high-quality silicon oxide film having a thin film thickness of about 1 nm or less.

Conventionally, a thermal oxidation has been used to form an oxide film on a silicon surface. However, the thermal oxidation performed at a high temperature of about 1000° C. causes thermal damage such as rediffusion of doped impurities and the like. Further, the thermal oxidation such as an LP-CVD (Low Pressure-Chemical Vapor Deposition), a RTO (Rapid Thermal Oxidation) or the like is disadvantageous in that it is difficult to control a film thickness when forming a thin film of a few nanometers.

Meanwhile, as for a technique for forming a silicon oxide film by a plasma processing, there has been suggested a method for performing an oxidation process on a surface of a silicon substrate using a processing gas containing at least O₂ gas and a rare gas by a plasma processing apparatus having a partition plate provided with an opening (e.g., International Publication WO2004/047157, hereinafter referred to as “Patent Document 1”).

In general, when an oxide film is formed by a plasma oxidation process, the oxide film thus formed, a base layer or the like may be damaged by ions in the plasma or the like. Therefore, in Patent Document 1, a partition wall having an opening is provided to reduce the plasma damage by decreasing energy and density of ions in the plasma. However, in a case where an oxide film especially having a film thickness of about 1 nm or less needs to be formed, it is difficult to control the film thickness. Accordingly, the film thickness may become too thick due to an excessive oxidation, and a film thickness difference may be caused between portions. Especially, in the case of a large substrate having a diameter of about 300 mm or more, the uniformity of the film thickness deteriorates. Although the method described in Patent Document 1 can reduce the plasma damage by using the partition plate having an opening, it has not been examined whether or not the above method can be applied to the case of forming an oxide film having a thin film thickness of about 1.5 nm or less (especially, about 1 nm or less).

### SUMMARY OF THE INVENTION

In view of the above, the present invention provides a plasma processing apparatus and a plasma processing method capable of controlling a film thickness of a thin film in forming a silicon oxide film or the like by using a plasma.

In accordance with an aspect of the invention, there is provided a plasma processing apparatus including: a processing chamber for accommodating therein a target substrate; a substrate supporting table for mounting thereon the target substrate in the processing chamber; and a plasma bending unit for allowing a plasma to flow along non-linear passageways of a processing gas supplied from an upper portion of the processing chamber toward the target substrate mounted on the substrate supporting table.

The plasma bending unit may be formed by arranging at least two plates each having a plurality of through holes in such a manner that the through holes of the respective plates are not overlapped with each other. In this case, the plates may be made of a dielectric material. Further there may be provided, between the plates, a gap adjusting member for adjusting a gap between the plates. At this time, the gas adjusting member may be an annular member.

The plasma bending unit may be a plate made of a porous dielectric material. In this case, the porous dielectric material may have porosity ranging from about 70% to 80%.

The plasma processing apparatus may further include a planar antenna having a plurality of slots for introducing a microwave into the processing chamber.

In accordance with another aspect of the invention, there is provided a plasma processing method for forming a silicon oxide film by performing an oxidation process for oxidizing silicon on a surface of a target substrate by using an oxygen-containing plasma in a processing chamber of a plasma oxidation apparatus, wherein the oxidation process is performed in a state that a plasma bending unit for allowing the oxygen-containing plasma to flow along non-linear passageways is provided between the target substrate and a plasma generation region in the processing chamber.

The plasma bending unit may be formed by arranging at least two plates having a plurality of through holes in such a way that the through holes of the respective plates are not overlapped with each other. In this case, the plates may be made of a dielectric material.

The plasma bending unit may be a plate made of a porous dielectric material. At this time, porous dielectric material may have porosity ranging from about 70% to 80%.

Preferably, the silicon oxide film thus formed has a film thickness smaller than or equal to about 1 nm. Further, oxygen-containing plasma may be formed by introducing a microwave into the processing chamber with the use of a planar antenna having a plurality of slots.

The plasma processing apparatus of the present invention includes a plasma bending unit for allowing a plasma passing therethrough to flow along non-linear passageways. Therefore, the progress of oxidation reaction or nitridation reaction can be controlled by suppressing the action of ions in the plasma. For example, even a silicon oxide film having a thickness of about 1.5 nm or less, especially about 1 nm or less, can be formed while controlling the film thickness with high precision. Further, the formed oxide film has good uniformity and thus is widely used in a manufacturing process of semiconductor devices that are on miniaturizing.

### BRIEF DESCRIPTION OF THE DRAWINGS

FIG. 1 shows a schematic cross sectional view of an example of a plasma oxidation apparatus in accordance with a first embodiment of the present invention.

FIG. 2A provides a top view of a dual plate structure.

FIG. 2B is a cross sectional view of the dual plate structure.

FIG. 3 illustrates an antenna member.

FIG. 4 is a principal view for explaining a function of the dual plate structure.

FIG. 5A presents a schematic view of a cross sectional structure of a wafer in which devices are isolated from each other in a manufacturing process of a transistor.

FIG. 5B represents a schematic view showing a state where a plasma oxidation process is being performed to form a gate insulating film in the manufacturing process of the transistor.

FIG. 5C offers a schematic view illustrating a state where the transistor has been formed.

FIG. 6 depicts a schematic cross sectional view of an example of a plasma oxidation apparatus in accordance with a second embodiment of the present invention.

FIG. 7 describes a schematic cross sectional view of an example of a plasma oxidation apparatus in accordance with a third embodiment of the present invention.

FIG. 8 is a schematic cross sectional view of an example of a plasma oxidation apparatus in accordance with a fourth embodiment of the present invention.

FIG. 9 shows a schematic cross sectional view of an example of a plasma oxidation apparatus in accordance with a fifth embodiment of the present invention.

FIG. 10 provides a schematic cross sectional view of an example of a plasma oxidation apparatus in accordance with a sixth embodiment of the present invention.

FIG. 11 presents a graph describing a relationship between processing time of a plasma oxidation process and a film thickness of an oxide film in Test example 1 and Comparative example 1.

FIG. 12 represents a graph depicting a relationship between processing time of a plasma oxidation process and a film thickness of an oxide film in Test example 2 and Comparative example 2.

FIG. 13 illustrates a graph showing a relationship between the processing time of the plasma oxidation process and uniformity of the oxide film in Test example 2 and Comparative example 2.

FIG. 14 sets forth a graph illustrating relationships between processing time of a plasma oxidation process and a film thickness of an oxide film, and between the processing time and uniformity of the oxide film in Test example 3.

FIG. 15 offers a graph showing a relationship between a film thickness of an oxide film and uniformity thereof in a plasma oxidation process in Test examples 4 to 6.

FIG. 16 describes a graph illustrating a relationship between processing time of the plasma oxidation process and the film thickness of the oxide film in the Test examples 4 to 6.

FIG. 17 shows a diagram for explaining a gap ring.

FIG. 18 is a diagram for explaining another example of the dual plate structure.

FIG. 19 depicts a diagram for explaining still another example of the dual plate structure.

### DETAILED DESCRIPTION OF THE EMBODIMENT

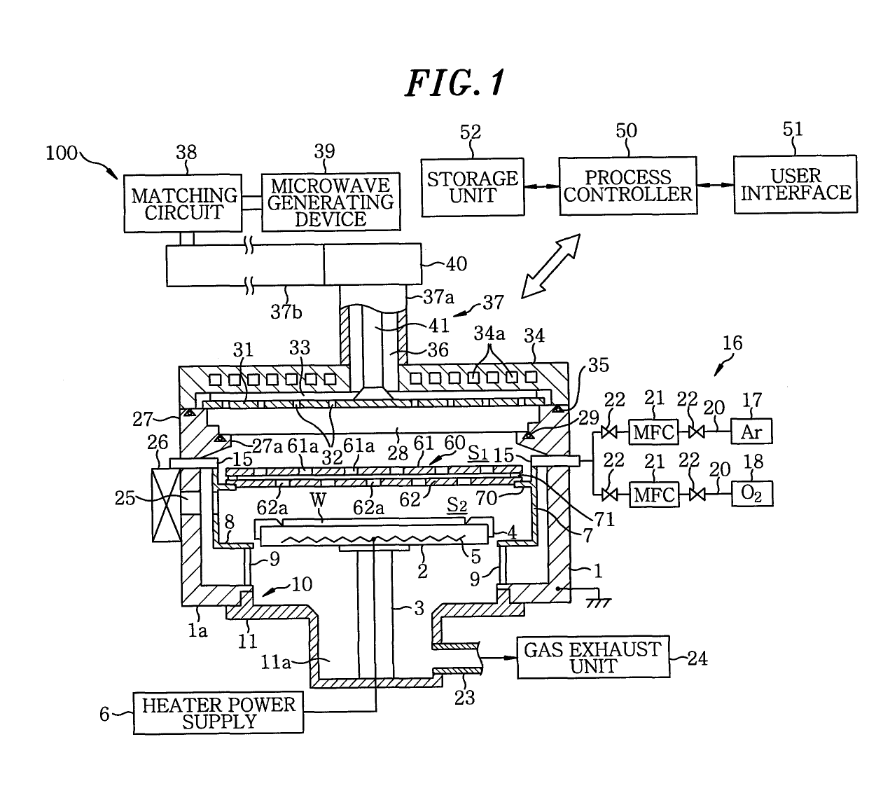

Hereinafter, embodiments of the present invention will be described with reference to the accompanying drawings. In the drawings, like parts are designated by like reference numerals. FIG. 1 is a schematic cross sectional view of an example of a plasma oxidation apparatus in accordance with a first embodiment of the present invention. The plasma oxidation apparatus is configured as an RLSA (radial line slot antenna) microwave plasma oxidation apparatus capable of generating a microwave plasma of a high density and a low electron temperature by introducing microwaves into a processing chamber by using a planar antenna having a plurality of slots, particularly an RLSA. Further, in a manufacturing process of various semiconductor devices, e.g., a MOS transistor, a MOSFET (field-effect transistor) and the like, the plasma oxidation apparatus can be suitably used to form a silicon oxide film. Moreover, by introducing a nitrogen-containing gas as a processing gas, it can also serve as a plasma nitridation apparatus for forming a silicon nitride film.

The plasma processing apparatus 100 includes a substantially cylindrical airtight chamber 1 that is grounded. A circular opening 10 is formed at a substantially central portion of a bottom surface 1a of the chamber 1, and an exhaust chamber 11 projecting downward is provided on the bottom surface 1a while communicating with the opening 10.

A susceptor 2 made of a ceramic, e.g., AlN or the like, is provided in the chamber 1 to horizontally support a silicon wafer (hereinafter, referred to as a “wafer”) W as a target object. Further, the susceptor 2 is supported by a cylindrical supporting member 3 extending upward from a central bottom portion of the exhaust chamber 11, the supporting member 3 being made of ceramic, e.g., AlN or the like. A guide ring 4 for guiding the wafer W is provided on an outer periphery portion of the susceptor 2. Moreover, a resistance heater 5 is buried in the susceptor 2 to heat the susceptor 2 by a power supplied from a heater power supply 6. The wafer W as a target object is heated by heat thus generated. At this time, the temperature of the wafer W can be controlled, e.g., between the room temperature and about 800° C. Besides, a cylindrical liner 7 made of quartz is provided on an inner periphery of the chamber 1 in order to prevent metal contamination caused by constituent materials of the chamber. Accordingly, an inside of the chamber is maintained in a clean environment. In addition, an annular baffle plate 8 having a plurality of through holes (not shown) is provided at a periphery of the susceptor 2 to thereby uniformly exhaust the inside of the chamber 1. The baffle plate 8 is supported by a plurality of support columns 9, and can be made of a material such as quartz, ceramic or the like.

The susceptor 2 is provided with wafer supporting pins (not shown) for supporting and vertically moving the wafer W. The wafer supporting pins can be protruded from or retracted into the top surface of the susceptor 2.

Provided above the susceptor 2 is a dual plate structure 60 serving as a plasma bending unit for allowing a plasma to flow along non-linear passageways. Due to the presence of the dual plate structure 60, labyrinth passageways are formed. A first and a second space S₁ and S₂ are formed above and under the dual plate structure 60 respectively. As shown in FIG. 1, the dual plate structure 60 includes an upper plate 61 having through holes 61a and a lower plate 62 having through holes 62a. When passing through the upper and the lower plate 61 and 62, the plasma flows along non-linear passageways formed by the upper and the lower plate 61 and 62. Therefore, ions in the plasma are trapped and prevented from being linearly supplied to the wafer W, which decreases ion energy. Further, the upper and the lower plates 61 and 62 are made of, e.g., a dielectric material such as quartz, sapphire, SiN, SiC, Al₂O₃ or AlN, or silicon such as single crystalline silicon or polycrystalline silicon.

In this embodiment, the upper and the lower plate 61 and 62 are made of high-purity quartz material having a very small amount of impurities such as metals or alkaline metals. For example, it is preferable to use a quartz member containing total impurities of about 50 ppm or less.

The upper and the lower plate 61 and 62 are connected with each other at a plurality of locations by coupling members 71 provided near peripheral portions thereof, and are spaced from each other in parallel by a predetermined distance (to be described later). The coupling members 71 also serve as a spacer for adjusting the distance between the upper plate 61 and the lower plate 62. Further, the lower plate 62 is supported by the engagement between an outer peripheral portion thereof and a support portion 70 projected inward from the liner 7 in the chamber 1 along the entire periphery.

Preferably, the plates 61 and 62 are attached near the wafer W. A distance between the bottom surface of the lower plate 62 and the wafer W is preferably in a range, e.g., from about 3 to 20 mm, and more preferably about 10 mm. In this case, a distance between the top surface of the upper plate 61 and the bottom surface of a microwave transmitting plate 28 (to be described later) is preferably in a range, e.g., from about 20 to 50 mm, and more preferably about 35 mm.

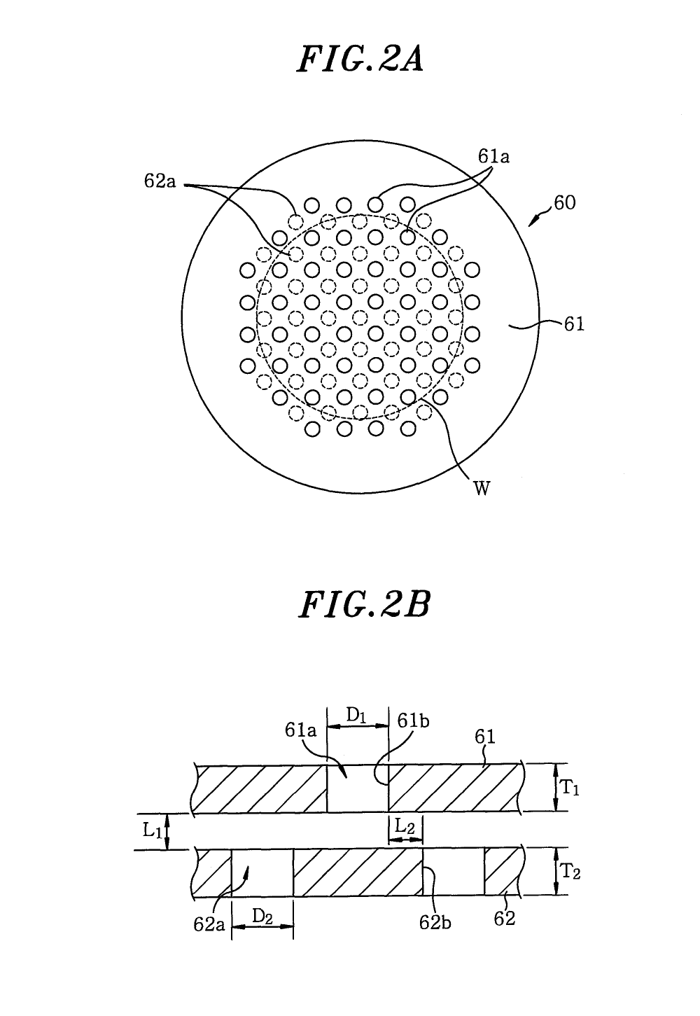

The upper and the lower plate 61 and 62 of the dual plate structure 60 have a plurality of through holes 61a and 62a, respectively. FIGS. 2A and 2B illustrate detailed views of the upper and the lower plate 61 and 62. Specifically, FIG. 2A shows a top view of the upper and the lower plate 61 and 62 that are overlapped, and FIG. 2B depicts a cross sectional view of principal parts of the upper and the lower plates 61 and 62 that are overlapped.

Preferably, a thickness T₁ of the upper plate 61 and a thickness T₂ of the lower plate 62 are in a range, e.g., from about 2 to 10 mm, and more preferably about 5 mm. Further, the thicknesses T₁ and T₂ of the upper and the lower plate 61 and 62 are not necessarily the same.

Moreover, a distance L₁ between the two plates 61 and 62 is preferably in a range, e.g., from about 3 to 10 mm, and more preferably about 5 mm.

The through holes 61a of the upper plate 61 and the through holes 62a of the lower plate 62 are substantially uniformly distributed to cover an area for mounting the wafer W which is indicated by a dashed line in FIG. 2A. As shown in FIGS. 2A and 2B, the through holes 61a of the upper plate 61 and the through holes 62a of the lower plate 62 are misaligned so that they are not overlapped with each other in a state where the two plates 61 and 62 are overlapped. In other words, the through holes 61a and 62a are disposed to form a labyrinth structure in which no linear passageways are formed from the space above the upper plate 61 to a surface of the wafer W.

A diameter D₁ of the through holes 61a and a diameter D₂ of the through holes 62a can be arbitrarily set. In this embodiment, they are set to be about 5 mm, for example. Further, the diameter of the through holes 61a or 62a may vary depending on positions thereof in the same plate. Moreover, the through holes 61a of the upper plate 61 may have a diameter different from that of the through holes 62a of the lower plate 62. In addition, the arrangement pattern of the through holes 61a and 62a may be arbitrarily selected among a concentric circular pattern, a radial pattern, a spiral pattern, a lattice pattern, a zigzag pattern or the like, as long as the holes of the upper plate and the lower plate 61 and 62 are not overlapped with each other. Besides, the shape of the through holes 61a and 62a may be selected among an angled shape, such as a triangular shape, a square shape or the like, an elliptical shape, a slit shape or the like.

The misalignment between the adjacent through holes 61a and 62a, i.e., the distance L₂ between the side wall 61b of the through hole 61a of the upper plate 61 and the side wall 62b forming the through hole 62a of the lower plate 62, can be determined optimally based on the relationship with the distance L₁ between the upper and the lower plate 61 and 62.

That is, in order to restrict the passage of ions in the plasma, when the distance L₁ between the upper and the lower plate 61 and 62 increases, the distance L₂ should be comparatively increased. Further, when the distance L₁ decreases, it is possible to trap the ions in the plasma even if the distance L₂ is comparatively decreased. The function for restricting the passage of ions can be maximized by considering not only the relationship between L₁ and L₂, but also the thicknesses T₁ and T₂ of the upper and the lower plates 61 and 62 (i.e., the heights of the walls 61b and 62b), the diameters D₁ and D₂ of the through holes 61a and 62a, the shape or the arrangement pattern of the through holes 61a and 62a, the installation areas of the upper and the lower plate 61 and 62 (the distance from the wafer W) and the like.

Referring back to FIG. 1, an annular gas introducing member 15 is provided on a sidewall positioned above the dual plate structure 60 in the chamber 1, and a gas supply system 16 is connected thereto. The gas introducing member 15 may be disposed in a form of a nozzle shape or a shower shape. The gas supply system 16 includes, e.g., an Ar gas supply source 17 and an O₂ gas supply source 18, and these gases are supplied to the gas introducing member 15 through respective gas lines 20, and then are introduced from the gas introducing member 15 into the chamber 1. Each of the gas lines 20 is provided with a mass flow controller 21 and opening/closing valves 22 disposed at an upstream and a downstream of the mass flow controller 21. Instead of the Ar gas, a rare gas such as He, Kr, Xe or the like can be used.

A gas exhaust line 23 is connected on a side surface of the exhaust chamber 11, and a gas exhaust unit 24 including a high speed vacuum pump is connected with the gas exhaust line 23. By operating the gas exhaust unit 24, a gas in the chamber 1 is uniformly discharged into a space 11a of the exhaust chamber 11 via the baffle plate 8 and then is exhausted through the gas exhaust line 23. Accordingly, the inside of the chamber 1 can be depressurized to a predetermined vacuum level, e.g., about 0.133 Pa, at a high speed.

Provided on the sidewall of the chamber 1 are a loading/unloading port 25 for transferring the wafer W between the chamber 10 and a transfer chamber (not shown) adjacent to the plasma processing apparatus 100 and a gate valve 26 for opening and closing the loading/unloading port 25.

An upper portion of the chamber 1 has an opening, and an annular upper plate 27 is connected with the opening. A lower portion of an inner periphery of the upper plate 27 is projected toward an inner space of the chamber to form an annular support portion 27a. A microwave transmitting plate 28 made of a dielectric material, e.g., quartz or ceramic such as Al₂O₃, AlN, or the like, is airtightly disposed on the support portion 27a via a sealing member 29. Therefore, the inside of the chamber 1 is airtightly maintained.

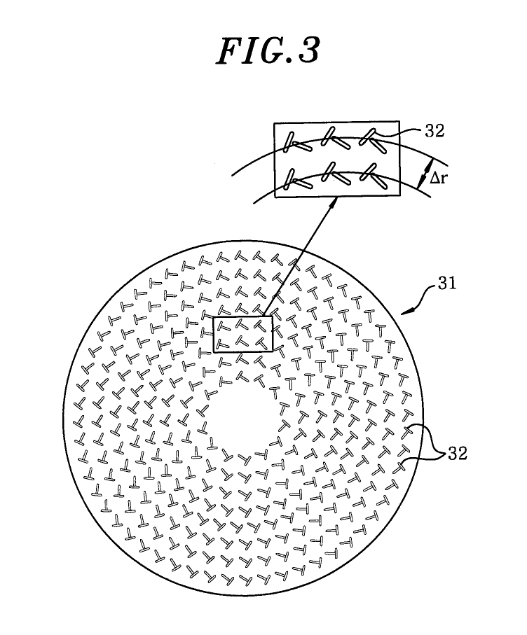

An antenna member 31 is provided on the microwave transmitting plate 28 while facing the susceptor 2. The antenna member 31 is formed as, e.g., a disc-shaped planar antenna, and is fixed to a top portion of the sidewall of the chamber 1. The antenna member 31 is made of, e.g., an aluminum plate or a copper plate coated with gold or silver, and has a plurality of microwave radiation holes (slots) 32 formed therethrough in a predetermined pattern. For example, the microwave radiation holes 32 have an elongated shape, as shown in FIG. 3, and typically, the adjacent microwave radiation holes 32 are disposed in a T shape. The plurality of microwave radiation holes 32 is concentrically disposed. A length of the microwave radiation hole 32 or an arrangement interval therebetween is determined depending on a wavelength λg of the microwave.

For example, the microwave radiation holes 32 are spaced apart from each other at the interval of λg/4, λg/2 or λg. Further, in FIG. 3, the interval between the adjacent microwave radiation holes 32 that are concentrically disposed is indicated as Δr. Further, the microwave radiation holes 32 may have another shape, e.g., a circular shape, an arc shape or the like. Further, the microwave radiation holes 32 can be arranged in another pattern, e.g., a spiral pattern, a radial pattern or the like, without being limited to the concentric circular pattern. Furthermore, the antenna member 31 can be formed in a square plate shape. In that case, the microwave radiation holes 32 may be linearly arranged in plural rows, and the adjacent rows of the microwave radiation holes 32 may be disposed in parallel with each other.

Provided on a top surface of the antenna member 31 is a retardation member 33 having a dielectric constant greater than that of a vacuum. The retardation member 33 is preferably made of, e.g., quartz, a fluorine-based resin such as polytetrafluoroethylene or the like, a polyimide resin, or the like. The retardation member 33 has a function of shortening the wavelength of the microwave. Since the wavelength of the microwave becomes longer in the vacuum, the wavelength of the microwave needs to be shortened by the retardation member 33 to thereby efficiently supply the microwave to the microwave radiation holes 32. Although the antenna member 31 may be in contact with or separated from the microwave transmitting plate 28 and the retardation member 33, it is preferable that they are in contact with each other.

A shield lid 34 made of a metal material, e.g., aluminum, stainless steel or the like, is provided on a top surface of the chamber 1 to cover the antenna member 31 and the retardation member 33. The shield lid 34 also serves as a waveguide for propagating the microwave in a planar direction. The top surface of the chamber 1 and the shield lid 34 are sealed by sealing members 35. Cooling water paths 34a are formed in the shield lid 34, so that the shield lid 34, the retardation member 33, the antenna member 31 and the microwave transmitting plate 28 can be cooled by circulating cooling water through the wafer paths 34a. By cooling these members, the retardation member 33, the antenna member 31 and the microwave transmitting plate 28 can be protected from thermal deformation or damage, so that a stable plasma can be obtained. Further, the shield lid 34 is grounded.

The shield lid 34 has an opening 36 at a center of a top wall thereof, and a waveguide 37 is connected with the opening. A microwave generating device 39 is connected with an end portion of the waveguide 37 via a matching circuit 38. Accordingly, a microwave having a frequency of, e.g., 2.45 GHz, which is generated from the microwave generating device 39, is propagated to the antenna member 31 via the waveguide 37. The microwave may have a frequency of 8.35 GHz, 1.98 GHz or the like.

The waveguide 37 includes a coaxial waveguide 37a having a circular cross section and extending upward from the opening 36 of the shield lid 34, and a rectangular waveguide 37b extending in a horizontal direction and connected with an upper portion of the coaxial waveguide 37a via a mode transducer 40. The mode transducer 40 between the rectangular waveguide 37b and the coaxial waveguide 37a has a function of converting a TE mode of the microwave propagating in the rectangular waveguide 37b into a TEM mode. An internal conductor 41 is extended in the coaxial waveguide 37a, and a lower portion of the internal conductor 41 is fixedly connected to a center of the antenna member 31. As a consequence, the microwave is efficiently and uniformly propagated to the antenna member 31 via the internal conductor 41 of the coaxial waveguide 37a radially.

Each component of the plasma processing apparatus 100 is connected with a process controller 50 having a CPU and controlled by the process controller 50. The process controller 50 is connected with a user interface 51 having a keyboard, a display and the like. A process operator uses the keyboard when inputting commands for managing the plasma processing apparatus 100, and the display is used to display the operation status of the plasma processing apparatus 100.

Further, the process controller 50 is connected with a storage unit 52 for storing therein control programs (software) for implementing various processes in the plasma processing apparatus 100 under the control of the process controller 50, and recipes including processing condition data and the like.

If necessary, the process controller 50 executes a recipe read from the storage unit 52 in response to instructions from the user interface 51, thereby implementing a required process in the plasma processing apparatus 100 under the control of the process controller 50. Further, the control programs or the recipes such as the processing condition data and the like can be stored in a computer-readable storage medium, e.g., a CD-ROM, a hard disk, a flexible disk, a flash memory or the like, or transmitted on-line from another device via, e.g., a dedicated line when necessary.

In the RLSA type plasma processing apparatus 100 configured as described above, a process for forming a silicon oxide film by oxidizing a silicon layer of the wafer W can be performed according to the following sequences.

First, the gate valve 26 is opened, and the wafer W having the silicon layer formed thereon is loaded into the chamber 1 through the loading/unloading port 25. Next, Ar gas and O₂ gas are introduced from the Ar gas supply source 17 and the O₂ gas supply source 18 of the gas supply system 16 into the chamber 1 through the gas introducing member 15 at predetermined flow rates, respectively.

Specifically, the flow rate of the rare gas such as Ar or the like and the flow rate of the O₂ gas are set to be in a range from about 200 to 3000 mL/min(sccm) and from about 1 to 600 mL/min(sccm), respectively. A processing pressure in the chamber is controlled to be in a range from about 6.7 to 1333 Pa (from about 50 mTorr to 10 Torr), and preferably from about 26.6 to 400 Pa (about 200 mTorr to about 3 Torr). The wafer W is heated to a temperature ranging from about 300 to 800° C., and preferably from about 400 to 800° C. At this time, in order to form a silicon oxide film (SiO₂ film) having a thickness of about 1 nm or less and to enhance the controllability of the film thickness, a flow rate ratio of Ar/O₂ is preferably in a range from about 5 to 500, and more preferably from about 10 to 400.

Then, the microwave generated from the microwave generating device 39 is guided to the waveguide 37 via the matching circuit 38 and then is supplied to the antenna member 31 via the rectangular waveguide 37b, the mode transducer 40, the coaxial wave guide 37a and the internal conductor 41 in that sequential. Thereafter, the microwave is radiated through the microwave radiation holes of the antenna member 31 into a space above the wafer W in the chamber 1 via the microwave transmitting plate 28. The microwave propagates in the rectangular waveguide 37b in the TE mode. The TE mode of the microwave is converted into the TEM mode in the mode transducer 40, and the microwave propagates in the TEM mode through the coaxial waveguide 37a toward the antenna member 31. An electromagnetic field is formed in the chamber 1 by the microwave radiated from the antenna member 31 into the chamber 1 via the microwave transmitting plate 28, thereby converting Ar gas and O₂ gas into a plasma. At this time, the power of the microwave generating device 39 is preferably in a range from about 0.5 to 5 kW.

By radiating the microwave through the plurality of microwave radiation holes 32 of the antenna member 31, the plasma having a high density ranging from about 1×10¹¹ to 5×10¹²/cm³ and an electron temperature of about 1 to 2 eV is generated in the first space S₁ serving as a plasma generation region. In the second space S₂ provided under the dual plate structure 60, since the passage of ions having high energy is prevented and most of radicals are allowed to pass therethrough while the plasma passes through the dual plate structure 60, the electron temperature and the ion energy of the plasma are greatly reduced. It is believed that this is because of the following mechanism. The upper and the lower plate 61 and 62 are made of an insulating material and thus have a floating potential with respect to the plasma. Accordingly, a sheath having a potential difference is formed on the surfaces of the plates 61 and 62 (the wall surfaces of the plates 61 and 62 or the inner wall surfaces of the through holes 61a and 62a). As a result, the ions having high energy are accelerated by the sheath, and most of them are deactivated by collision with the plates 61 and 62. Meanwhile, the radicals that are neutral particles pass through the through holes 61a and 62a and then are supplied to the second space S₂ provided under the dual plate structure 60.

Due to the above mechanism, in the second space S₂ (i.e., between the wafer W and the plate 62) provided under the dual plate structure 60, the density of ions in the plasma can be reduced below about 1×10⁹ to 1×10¹¹/cm³ and the electron temperature can be reduced to be about 0.7 eV or less. Therefore, the plasma damage caused by ions or the like can be further reduced. Further, oxygen is introduced into the silicon by an action of active species, mainly oxygen radicals O*, in the plasma, thereby forming Si—O bond. As a result, a high-quality silicon oxide film is formed.

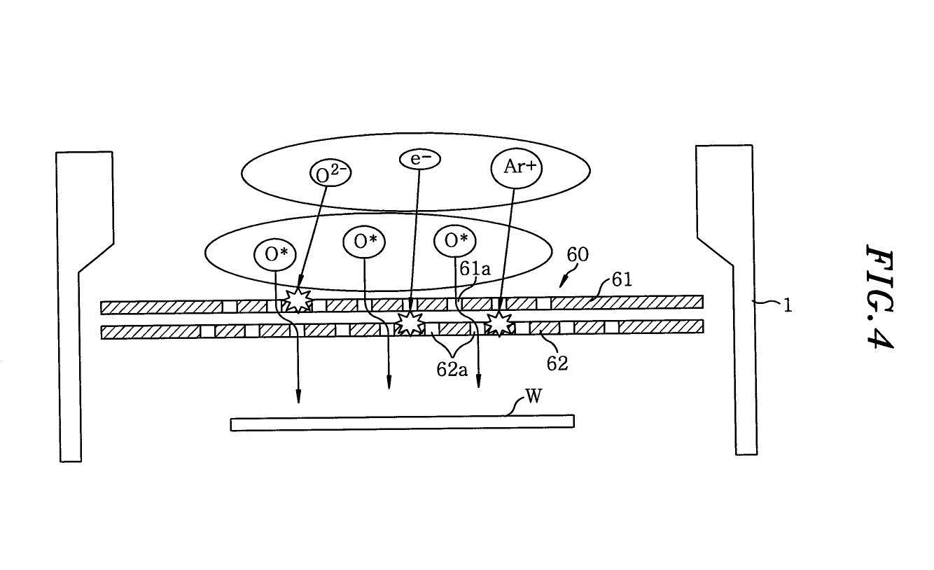

Hereinafter, the operation of the embodiment of the present invention will be described with reference to FIG. 4. FIG. 4 is a principal view schematically explaining a plasma oxidation process performed on the wafer W by the plasma oxidation apparatus 100. The plasma generated by the reaction between the Ar/O₂ gas and the microwave supplied from the antenna member 31 of the plasma oxidation apparatus 100 moves down toward the wafer W mounted on the susceptor 2 in the chamber 1. At this time, the plasma passes through the dual plate structure 60 (the upper and the lower plate 61 and 62) provided in the chamber, so that the ions in the plasma are trapped. As a result, the ion energy of the plasma decreases. The plasma is divided into a plurality of flows, when passing through the through holes 61a of the upper plate 61. These flows of the plasma join in the space between the upper plate 61 and the lower plate 62.

Then, the plasma is divided into a plurality of flows again when passing through the through holes 62a of the lower plate 62. These flows join again under the lower plate 62. Due to the presence of the dual plate structure 60 for forming labyrinth passageways, the ions in the plasma or the like are prevented from linearly reaching the wafer W. Moreover, as shown in FIG. 4, since electrons (e⁻) or ions by the plasma, e.g., Ar ions (Ar⁺), O₂ ions (O²⁻) or the like are charged particles, they are accelerated in the plasma sheath formed on the surfaces of the plates 61 and 62 made of an insulating material such as quartz or the like and collide with the plates 61 and 62. Accordingly, a large amount of ions in the plasma are deactivated, which reduces the ion energy. Further, the ion density in the plasma and the electron temperature decrease. Meanwhile, the oxygen radicals O* as neutral particles reach the wafer W after passing through the through holes 61a and 62a.

In order to control the passage of the ions in the plasma, it is important to form the through holes 61a and 62a of the upper and the lower plate 61 and 62 not to be overlapped with each other (see FIGS. 2A and 2B). With such an arrangement of the through holes 61a and 62a (the labyrinth structure), the passage of the ions in the plasma can be prevented while the oxygen radicals are selectively allowed to pass therethrough. The oxygen radicals that have passed through the upper and the lower plates 61 and 62 react with the exposed silicon on the wafer W, thereby forming an SiO₂ film (oxide film). Accordingly, by controlling the passage of ions, the excessive oxidation of the silicon is suppressed and the plasma processing of a low electron temperature can be performed.

Further, it is possible to control the film thickness to form a high-quality thin film having an extremely thin film thickness. The advantages of the plasma oxidation apparatus 100 is especially effective in forming a silicon oxide film (SiO₂ film), a silicon nitride film (SiN film) and a silicon oxynitride film (SiON film), all having a high density, a high quality and a very thin film thickness of about 1 nm or less, e.g., about 0.3 to 0.8 nm.

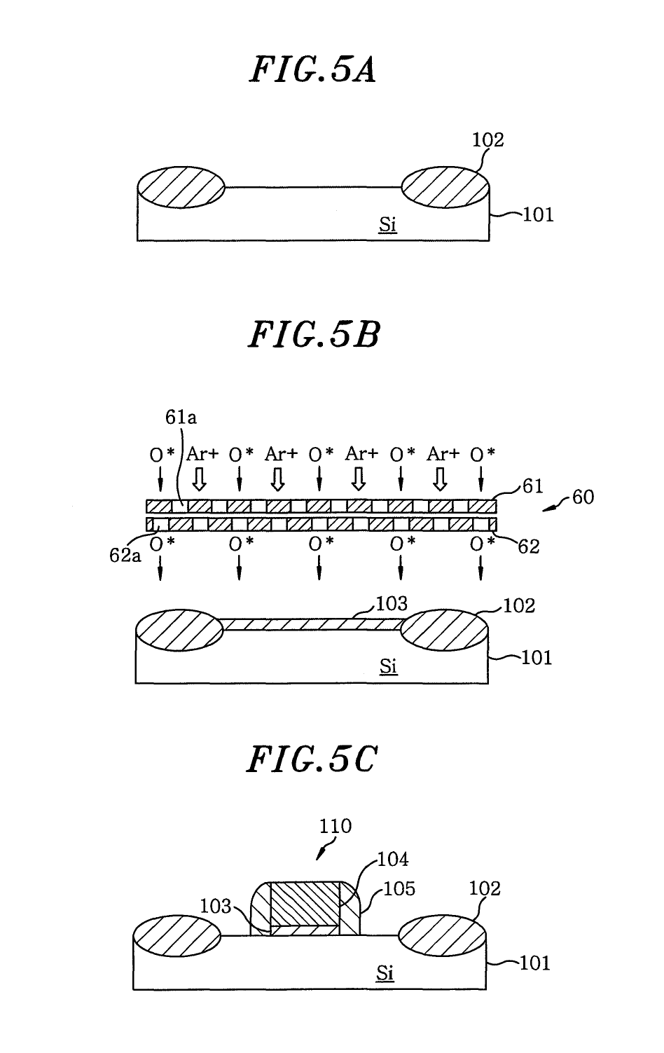

A method of the present invention can be applied to a manufacturing process of various semiconductor devices such as a MOS transistor and the like. FIGS. 5A to 5C explain an example of applying the plasma processing method in accordance with an embodiment of the present invention to a manufacturing process of a transistor.

As illustrated in FIG. 5A, a well (not shown) is formed on a P-type or an N-type Si substrate 101, and a device isolation layer 102 is formed by using, e.g., a LOCOS (Local Oxidation of Silicon) method. It is preferable to remove the oxide film by wet cleaning the silicon substrate 101 in advance by DHF (Diluted HF) solution having concentration of 1%. Further, the device isolation region 102 may be formed by an STI (Shallow Trench Isolation) method.

Next, as described in FIG. 5B, the plasma oxidation process is carried out, thereby forming a gate oxide film (SiO₂ film) 103 on a surface of the silicon substrate 101. In this plasma oxidation process, when the plasma passes through the dual plate structure 60 installed above the Si substrate 101 as a target object, the passage of the oxygen radicals is selectively allowed while the passage of most of the Ar ions in the plasma is blocked. Since the gate oxide film 103 is formed mainly by the action of the oxygen radicals, it is less damaged by the ions and thus has high quality. Although a film thickness of the gate oxide film 103 varies depending on a device to be fabricated, it is preferably about 1 nm or less, and more preferably in a range from about 0.3 to 0.8 nm.

Thereafter, a polysilicon layer 104 is formed on the gate oxide film 103 by, e.g., a CVD process. Then, a gate electrode is formed by etching the polysilicon layer 104 with a mask patterned by a photolithography technology. A gate electrode structure is not limited to a single layer structure of the polysilicon layer 104, but can be a laminated structure including, e.g., tungsten, molybdenum, tantalum, titanium, silicide thereof, nitride, alloy and the like, to thereby improve an operation speed of a device by reducing a resistivity of the gate electrode. Next, a source/drain (not shown) is formed on the gate electrode by performing an ion implantation and an activation process and, then, sidewalls 105 of an insulating film are formed, thereby fabricating a transistor 110 having a MOS structure as shown in FIG. 5C.

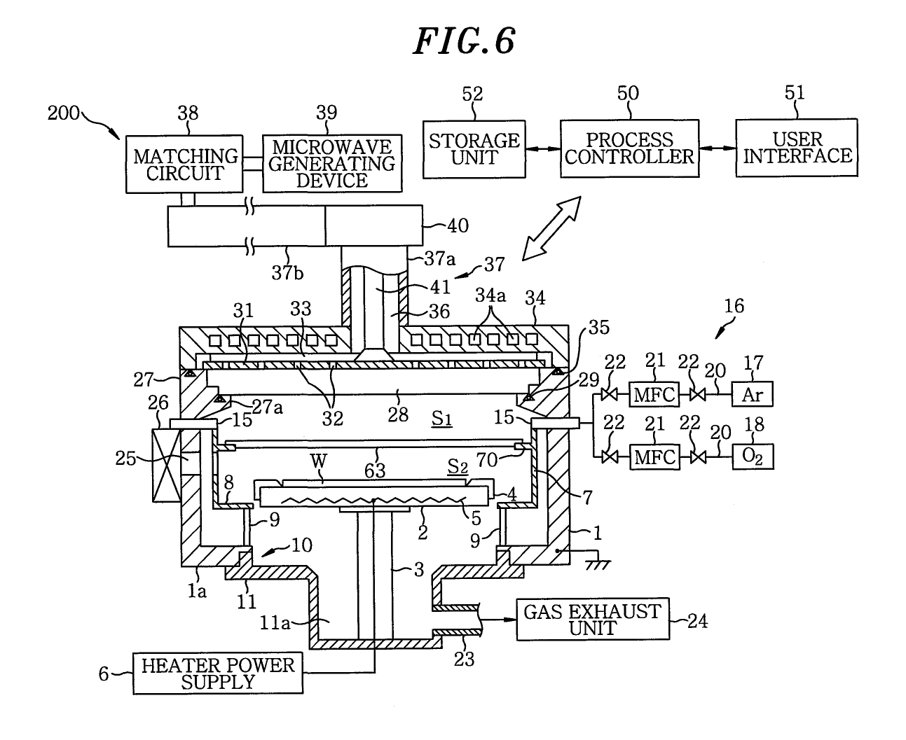

FIG. 6 depicts a schematic cross sectional view of an example of a plasma oxidation apparatus in accordance with a second embodiment of the present invention. In a plasma oxidation apparatus 200 of this embodiment, a porous plate 63 made of a quartz member is provided instead of the dual plate structure 60 of the plasma oxidation apparatus 100 of FIG. 1. The porous plate 63 has porosity of about 75%. When an oxygen-containing plasma passes through the pores, the ions in the plasma is deactivated by the collision with the porous plate 63. That is, as in the case of the dual plate structure 60 (FIG. 1) of the first embodiment, the porous plate 63 serves as the plasma bending unit.

For this purpose, the porosity of the porous plate 63 is preferably in a range from about 65 to 85%, and more preferably from about 70 to 80%. As for a material of the porous plate 63, a material other than quartz can be used as long as it is a porous dielectric material. Since the other configurations of the plasma oxidation apparatus 200 in accordance with the second embodiment shown in FIG. 6 are the same as those of the plasma oxidation apparatus 100 of FIG. 1, like reference numerals will be given to like parts, and redundant description thereof will be omitted.

As described above, the type of the plasma bending unit may vary as long as it has passageways for passing a plasma therethrough and, also, the corresponding passageways are not straight but has a bent labyrinth structure, as in the case of the dual plate structure 60 shown in FIG. 1 or the porous plate 63 illustrated in FIG. 3.

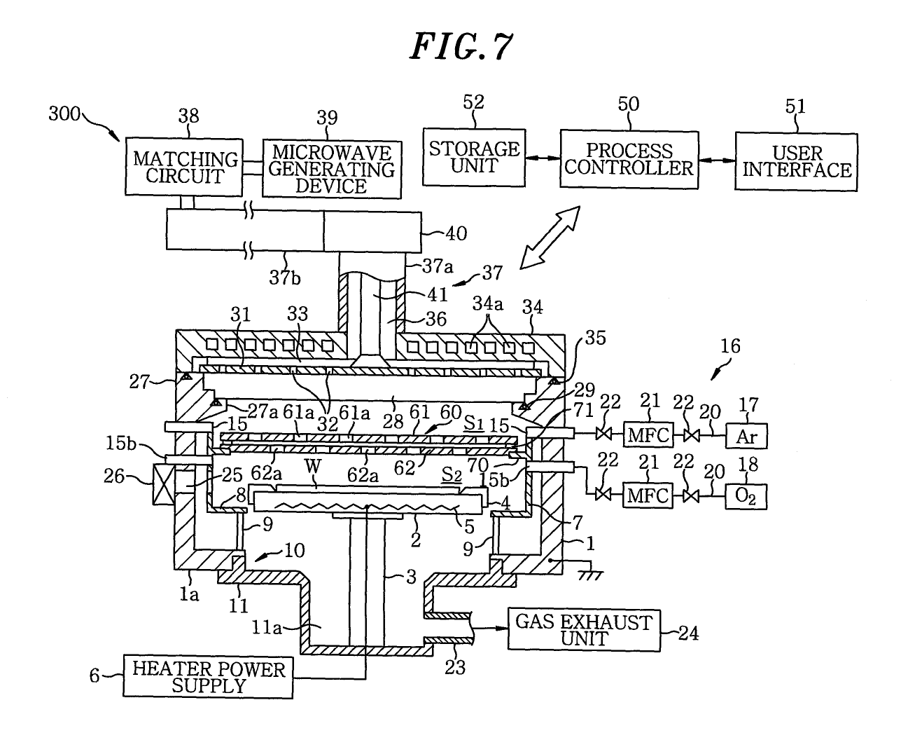

FIG. 7 describes a schematic cross sectional view of an example of a plasma oxidation apparatus in accordance with a third embodiment of the present invention. In a plasma oxidation apparatus 300 of this embodiment, gas introducing members 15a and 15b are provided above and below the dual plate structure 60. The gas introducing members 15a and 15b are formed in an annular shape on the sidewall of the chamber 1, and also are connected with the gas supply system 16. To be specific, the gas introducing members 15a and 15b are connected with the Ar gas supply source 17 and the O₂ gas supply source 18, respectively. The Ar gas and the O₂ gas are respectively supplied to the gas introducing members 15a and 15b through respective gas lines 20 and then are introduced into the chamber 1.

As described above, the gas inlet is divided into the gas introducing member 15a for introducing a rare gas such as Ar or the like and the gas introducing member 15b for introducing a reaction gas such as O₂ or the like and, also, the dual plate structure 60 is disposed therebetween. Accordingly, a plasma can be generated exclusively by the rare gas introduced into the space provided above the dual plate structure 60. When the plasma generated exclusively by the rare gas passes through the dual plate structure 60, the ion energy and the electron temperature decrease. Therefore, the oxidation process can be performed while the dissociation of the reaction gas is suppressed by the low-energy ions by introducing the reaction gas such as O₂ or the like into the space provided under the dual plate structure 60. Moreover, instead of the Ar gas, a rare gas such as He, Kr, Xe or the like can be used. Since the other configurations of the plasma oxidation apparatus 300 in accordance with the third embodiment shown in FIG. 7 are the same as those of the plasma oxidation apparatus 100 of FIG. 1, like reference numerals will be given to like parts, and redundant description thereof will be omitted.

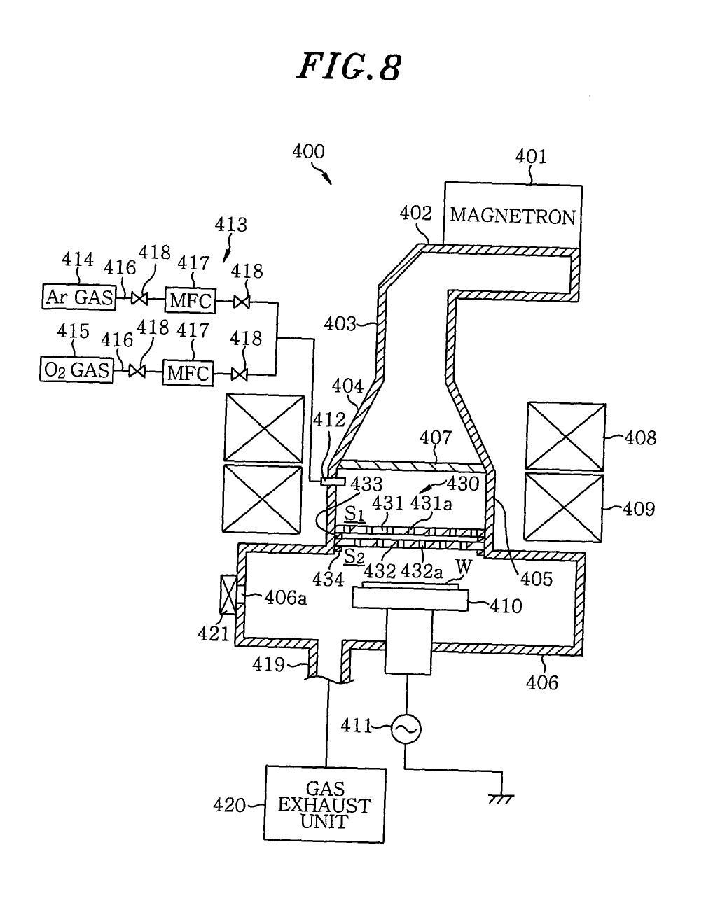

FIG. 8 is a cross sectional view showing a schematic configuration of a plasma oxidation apparatus 400 in accordance with a fourth embodiment of the present invention. The plasma oxidation apparatus 400 is configured as an ECR (Electron Cyclotron Resonance) microwave plasma processing apparatus. Reference numeral 401 indicates a magnetron serving as an oscillation source of a microwave. The magnetron 401 is connected with a discharge chamber 405 via a rectangular waveguide 402, a circular waveguide 403 and a tapered waveguide 404. The discharge chamber 405 is made of a material such as high-purity aluminum or the like. A vacuum chamber 406 is provided below the discharge chamber 405. A quartz plate 407 for supplying a microwave into the discharge chamber 405 is disposed between the tapered waveguide 404 and the discharge chamber 405. Provided around the discharge chamber 405 are solenoid coils 408 and 409 for applying a magnetic field into the discharge chamber 405.

A mounting table (susceptor) 410 for mounting thereon a wafer W is disposed under the discharge chamber 405. The susceptor 410 has a heating unit such as a resistance heater (not shown) or the like, and is connected with a bias RF power supply 411. Provided above the susceptor 410, i.e., between the quartz plate 407 and the susceptor 410, is a dual plate structure 430 serving as a plasma bending unit for allowing a plasma passing therethrough to flow along non-linear passageways. Due to the presence of the dual plate structure 430, labyrinth passageways are formed. A first space S₁ is formed above the dual plate structure 430, and a second space S₂ is formed under the dual plate structure 430. The dual plate structure 430 includes an upper plate 431 having through holes 431a and a lower plate 432 having through holes 432a. The structure and function of the dual plate structure 430 are the same as those of the dual plate structure 60 of the plasma processing apparatus 100 shown in FIG. 1, so that redundant description thereof will be omitted. Reference numerals 433 and 434 indicate supporting members for supporting the plates 431 and 432, respectively.

A gas inlet 412 is provided on a sidewall positioned above the dual plate structure 430 in the discharge chamber 405, and a gas supply system 413 is connected to the gas inlet 412. The gas supply system 413 includes, e.g., an Ar gas supply source 414 and an O₂ gas supply source 415, and these gases are supplied to the gas inlet 412 through respective gas lines 416, and then are introduced from the gas inlet 412 into the discharge chamber 405. Each of the gas lines 416 is provided with a mass flow controller 417 and opening/closing valves 418 disposed at an upstream and a downstream of the mass flow controller 417.

The vacuum chamber 406 is connected to a gas exhaust unit 420 having a vacuum pump for depressurizing and exhausting an inner space of the vacuum chamber 406 via a gas exhaust line 419, so that the inner space of the vacuum chamber 406 can be depressurized to a high vacuum state. Further, an opening 406a for loading/unloading the wafer W is formed on the sidewall of the vacuum chamber 406, and a gate valve 421 is provided at the outside thereof.

The magnetron 401 is attached to the rectangular waveguide 402, and oscillates a microwave of, e.g., 2.45 GHz. Meanwhile, a predetermined magnetic field is formed in the discharge chamber 405 by the solenoid coils 408 and 409. The processing gases are supplied from the gas supply unit 413 through the gas lines 416 and then are introduced into the discharge chamber 405 via the gas inlet 412. Further, the processing gases are converted into a plasma in the first space S₁ of the discharge chamber 405, and the wafer W is oxidized by the plasma mainly including radicals which has passed through the dual plate structure 430.

In the ECR plasma oxidation apparatus 400 as well, the presence of the dual plate structure 430 makes it possible to perform a plasma oxidation process capable of reducing a plasma damage and controlling a film thickness in high precision to form a thin film.

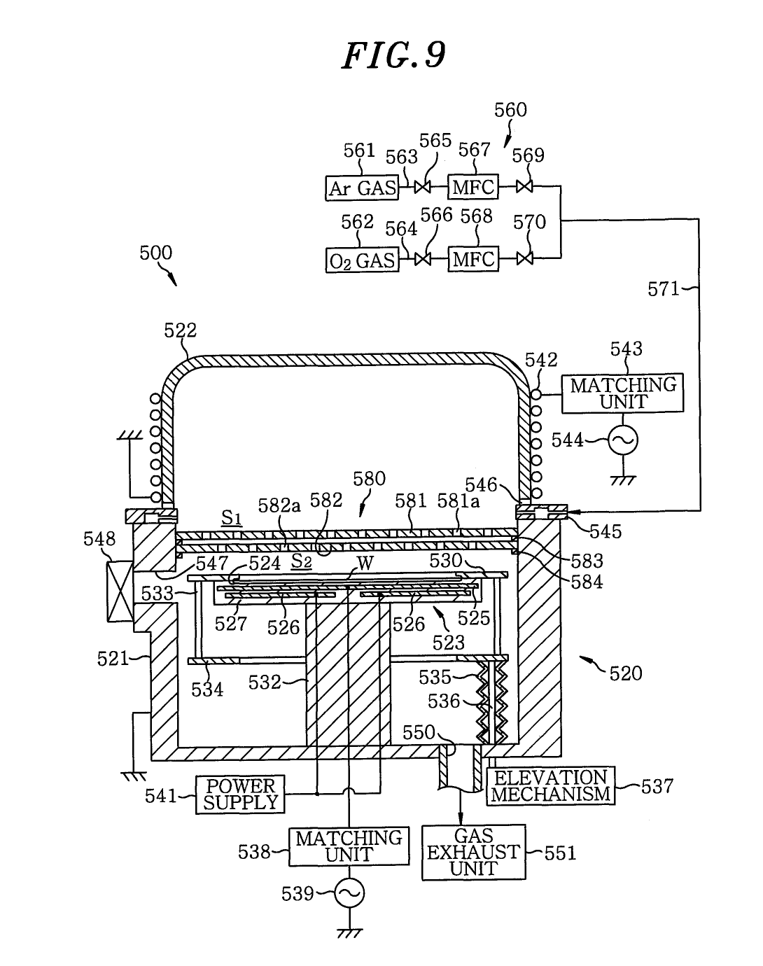

FIG. 9 presents a cross sectional view illustrating a schematic configuration of a plasma oxidation apparatus 500 in accordance with a fifth embodiment of the present invention. The plasma oxidation apparatus 500 is configured as an ICP (inductively coupled plasma) apparatus. As shown in FIG. 9, the plasma oxidation apparatus 500 includes a processing vessel 520 having: a cylindrical chamber 521 having an opened top, and a cylindrical bell jar 522 which is a lid provided on the chamber 521 via a gas supply unit 545 and a gasket 546. In the chamber 521, a susceptor (substrate mounting table) 523 for horizontally supporting the wafer W as a target object is supported by a cylindrical supporting member 532. A recess 524 having substantially the same shape as the wafer W is formed in a top surface of a susceptor body 527, and the wafer W is mounted on the recess 524. A disk-shaped meshy lower electrode 525 is buried below the recess 524, and a heating element 526 is buried below the lower electrode 525.

In other words, the susceptor 523 has a structure in which the lower electrode 525 for applying a bias voltage and the heating element 526 made of tungsten, molybdenum or the like are buried in the susceptor body (insulating member) 527 made of an insulating material, e.g., ceramic such as AlN, Al₂O₃ or the like. That is, the susceptor body 527 and the heating element 526 form a ceramics heater. The heating element 526 is connected to a DC power supply 541 so that the heating element 526 is heated by a power supplied from the power supply 541. As a consequence, the wafer W can be heated to a predetermined temperature.

An annular shadow ring 530 made of a dielectric material such as quartz, AlN, Al₂O₃ or the like is provided on the susceptor 523 to cover the edge of the wafer W mounted on the recess 524. The shadow ring 530 is connected to an annular member 534 via a supporting column 533 that is connected with a bottom surface of the shadow ring 530. The annular member 534 is connected to an elevating mechanism 537 via a rod-shaped member 536. When the rod-shaped member 536 is lifted up and down by the elevating mechanism 537, the annular member 534, the supporting column 533 and the shadow ring 530 can move vertically all together. The rod-shaped member 536 is surrounded by a bellows 535, so that the atmosphere in the processing vessel 520 can be prevented from leaking outside at the vicinity of the rod-shaped member 536.

Provided above the susceptor 523 is a dual plate structure 580 serving as a plasma bending unit for allowing a plasma to flow along non-linear passageways. Due to the presence of the dual plate structure 580, labyrinth passageways are formed. A first space S₁ is formed above the dual plate structure 580, and a second space S₂ is formed under the dual plate structure 580. The dual plate structure 580 includes an upper plate 581 having through holes 581a and a lower plate 582 having through holes 582a. The structure and function of the dual plate structure 580 are the same as those of the dual plate structure 60 of the plasma processing apparatus 100 shown in FIG. 1, so that redundant description thereof will be omitted. Reference numerals 583 and 584 indicate supporting members for supporting the plates 581 and 582, respectively.

A high frequency power supply 539 having a frequency of, e.g., 13.56 MHz, is connected with the lower electrode 525 via a matching unit 538. When the high frequency power supply 539 supplies electric power to the lower electrode 525, a predetermined bias voltage can be applied.

Further, the annular gas supply unit 545 and the gasket 546 are provided between the chamber 521 and the bell jar 522. A gas supplied from a gas supply mechanism 560 to be described later is introduced into the processing vessel 520 through gas discharge openings formed around an entire inner periphery of the gas supply unit 545. In addition, an opening 547 is formed on a sidewall of the chamber 521. Further, a gate valve 548 is provided at a position corresponding to the opening 47, outside the chamber 21. While the gate valve 548 is open, the wafer W is transferred between an adjacent load-lock chamber (not shown) and the chamber 521.

The bell jar 522 is made of an electrical insulating material such as quartz or ceramics. A coil 542 as an antenna serving as a plasma generating unit is wound around an outer periphery of the bell jar 522. The coil 542 is connected to a high frequency power supply 544 having a frequency of, e.g., 450 kHz, via a matching unit 543. When the high frequency power supply 544 supplies high frequency power to the coil 542 via the matching unit 543, an inductively coupled plasma (ICP) is generated in the bell jar 522.

The gas supply mechanism 560 has an Ar gas supply source 561 for supplying Ar gas and an O₂ gas supply source 562 for supplying O₂ gas. The Ar gas supply source 561 is connected with a gas line 563 provided with a mass flow controller 567 and opening/closing valves 565 and 569 disposed at an upstream and a downstream of the mass flow controller 567. Meanwhile, the O₂ gas supply source 562 is connected with a gas line 564 provided with a mass flow controller 568 and opening/closing valves 566 and 570 disposed at an upstream and a downstream of the mass flow controller 568. The gas lines 563 and 564 are connected with a gas line 571, and the gas line 571 is connected with the gas supply unit 545.

Further, a bottom wall of the chamber 521 is connected with a gas exhaust line 550. The gas exhaust line 550 is connected to a gas exhaust unit 551 having a vacuum pump. By operating the gas exhaust unit 551, an inner space of the processing vessel 520 can be maintained at a predetermined vacuum level.

The following is a description of a process for forming a silicon oxide film by oxidizing silicon on the wafer W by using the plasma oxidation apparatus 500 configured as described above.

First of all, the gate valve 548 is opened, and the wafer W is introduced into the chamber 521 by a transfer unit (not shown). Next, in a state where the shadow ring 530 covers, the wafer W is transferred onto wafer supporting pins (not shown) projected from the susceptor 523. Then, the wafer supporting pins and the shadow ring 530 are lowered, so that the wafer W is mounted on the susceptor 523 and the shadow ring 530 masks the outer peripheral portion of the wafer W. Thereafter, the gate valve 548 is closed, and the inner space of the processing vessel 520 is exhausted by the gas exhaust unit 551 and maintained at a predetermined depressurized state. In the depressurized state, Ar gas and O₂ gas are introduced at respective predetermined flow rates from the Ar gas supply source 561 and the O₂ gas supply source 562 into the processing vessel 520. At the same time, the high frequency power supply 544 starts to supply high frequency power to the coil 542. Accordingly, an inductively coupled plasma is generated in the bell jar 522, thereby forming active species of Ar, O₂ or the like. Moreover, the high frequency power supply 539 supplies high frequency power to the susceptor 523, so that a self-bias voltage is applied to the wafer W. As a consequence, the active species can be easily attracted to the wafer W.

In that state, the heating element 526 is heated by a power supplied from the power supply 541, so that the wafer W is heated to a predetermined temperature. Accordingly, the wafer W is oxidized in the chamber 521 by the plasma mainly including radicals which has passed through the dual plate structure 580. Next, the pressure in the processing vessel 520 is adjusted by controlling the flow rates of the gases supplied from the Ar gas supply source 561 and the O₂ gas supply source 562, while the supporting pins project from the susceptor 523 to lift up the wafer W. After the gate valve 48 is opened, the wafer W is unloaded by the transfer unit (not shown), thereby completing the processes of the plasma oxidation apparatus 500.

In the ICP plasma oxidation apparatus 500 as well, the presence of the dual plate structure 580 makes it possible to perform a plasma oxidation process capable of reducing a plasma damage and controlling a film thickness in high precision to form a thin film. The dual plate structure 580 can be also provided at an ICP plasma processing apparatus having, e.g., a hemispherical bell jar, other than the bell jar 522 having a flat top portion shown in FIG. 9.

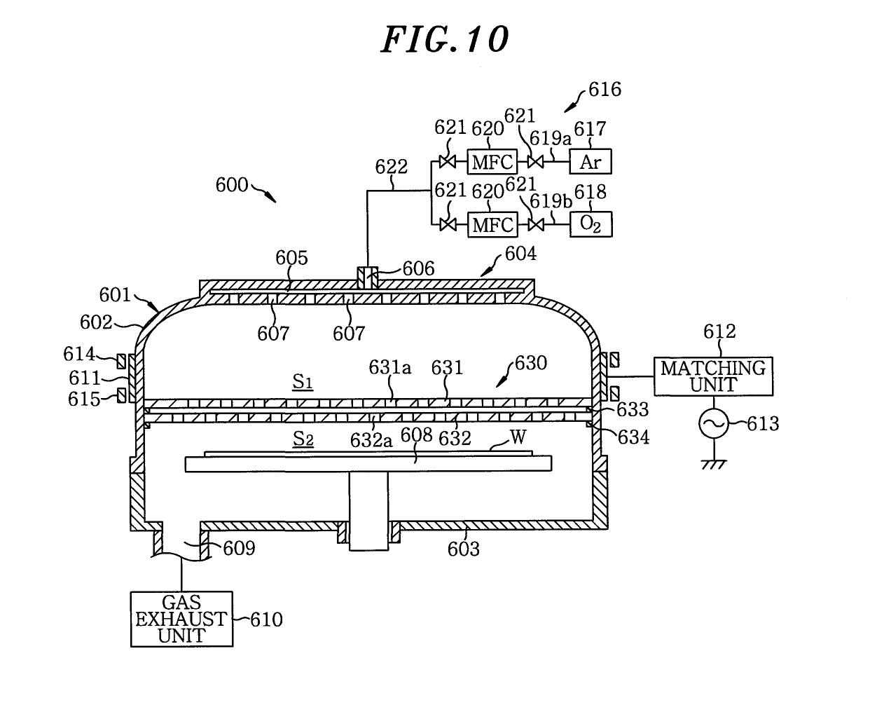

FIG. 10 provides a cross sectional view showing a schematic configuration of a plasma oxidation apparatus 600 in accordance with a sixth embodiment of the present invention. The plasma oxidation apparatus 600 is configured as a magnetron type apparatus. Further, the plasma oxidation apparatus 600 has a vacuum vessel 601 forming a processing chamber. The vacuum vessel 601 includes an upper vessel 602 and a lower vessel 603, both being coupled to each other vertically. The upper vessel 602 is made of ceramics such as alumina, quartz or the like, and the lower vessel 603 is made of metal.

The upper vessel 602 has a substantially flat ceiling portion, and the ceiling portion is provided with a shower head 604. A diffusion space 605 is formed in the shower head 604. A gas inlet 606 for introducing a processing gas is formed at a center of an upper portion of the shower head 604 and communicates with the diffusion space 605. Moreover, the shower head 604 has a plurality of openings 607 in a bottom portion thereof. The plural kinds of processing gases introduced from the gas inlet 606 are mixed and diffused in the diffusion space 605 and then are supplied to a processing space in the vacuum vessel 601 through the openings 607 of the shower head 604.

Disposed in the vacuum vessel 601 is a susceptor 608 as a mounting table for supporting the wafer W as a target object. The susceptor 608 has a heater (not illustrated) for heating the wafer W to a predetermined temperature. Further, the lower vessel 603 is provided with a gas exhaust port 609 connected with a gas exhaust unit 610 having a vacuum pump or the like.

A cylindrical electrode 611 is provided outside the upper vessel 602 around an outer peripheral surface of the upper vessel 602 while being spaced apart therefrom by a predetermined distance. The cylindrical electrode 611 is connected to a high frequency power supply 613 via a matching unit 612. The high frequency power supply 613 is configured to supply a high frequency power having a frequency of, e.g., 13.56 MHz, to the cylindrical electrode 611.

Moreover, two annular permanent magnets 614 and 615 are disposed around the upper vessel 602. These two permanent magnets 614 and 615 are magnetized in the diametrically opposite directions, thus forming in the vacuum vessel 601 magnetic force lines proceeding from the upper permanent magnet 614 to a central portion and then turning to the lower permanent magnet 615.

The gas supply mechanism 616 has an Ar gas supply source 617 for supplying Ar gas and an O₂ gas supply source 618 for supplying O₂ gas. The Ar gas supply source 617 is connected with a gas line 619a provided with a mass flow controller 620 and opening/closing valves 621 disposed at an upstream and a downstream of the mass flow controller 620.

Meanwhile, the O₂ gas supply source 618 is connected to a gas line 619b provided with a mass flow controller 620 and opening/closing valves 621 disposed at an upstream and a downstream of the mass flow controller 620. The gas lines 619a and 619b are connected with a gas line 622, and the gas line 622 is connected to the gas inlet 606.

Provided above the susceptor 608 is a dual plate structure 630 serving as a plasma bending unit for allowing a plasma passing therethrough to flow along non-linear passageways. Due to the presence of the dual plate structure 630, labyrinth passageways are formed. A first space S₁ is formed above the dual plate structure 630, and a second space S₂ is formed under the dual plate structure 630. The dual plate structure 630 includes an upper plate 631 having through holes 631a and a lower plate 632 having through holes 632a. The structure and function of the dual plate structure 631 are the same as those of the dual plate structure 60 of the plasma processing apparatus 100 shown in FIG. 1, so that redundant description thereof will be omitted. Reference numerals 633 and 634 indicate supporting members for supporting the plates 631 and 632, respectively.

The following is a description on a process sequence of the plasma oxidation apparatus 600. First of all, the wafer W is mounted on the susceptor 608 by a transfer unit (not shown). By operating the gas exhaust unit 610, a gas in the vacuum chamber 601 is exhausted via the gas exhaust port 609. Accordingly, the inner space of the vacuum vessel 601 is maintained in a vacuum state. Next, the susceptor 608 is heated, thereby heating the wafer W to a predetermined temperature.

Next, a processing gas supplied from the gas supply mechanism 616 is introduced through the gas inlet 606. The processing gas introduced through the gas inlet 606 is diffused in the diffusion chamber 605 and then is supplied to the first space S₁ through the openings 607 of the shower head 604. Further, a high frequency power is supplied from the high frequency power supply 613 to the cylindrical electrode 611. The magnetic force lines are formed in the vacuum vessel 601 by the permanent magnets 614 and 615 and a high frequency electric field is formed by the cylindrical electrode 611, thus generating a plasma. The wafer W on the susceptor 608 processed by the generated plasma, thereby forming, e.g., a silicon oxide film. At this time, in the vacuum vessel 601, the wafer W is oxidized by the plasma mainly including radicals which has passed through the dual plate structure 630. After a predetermined period of time elapses, the supply of the high frequency power from the high frequency power supply 613 is stopped and, then, the gas in the vacuum vessel 601 is exhausted through the gas exhaust port 609. Next, the wafer W on the susceptor 608 is unloaded from the vacuum vessel 601 by using the transfer unit (not illustrated), thereby completing the processes.

As set forth above, in the plasma oxidation apparatus 600, a magnetron discharge is generated in the vacuum vessel 601 by the magnetic fields of the permanent magnets 614 and 615 and a high-density plasma is generated in a space provided above the wafer W. Then, a plasma oxidation process is performed on the surface of the wafer W on the susceptor 608 by the generated high-density plasma. Therefore, in the magnetron ICP plasma oxidation apparatus 600 as well, the presence of the dual plate structure 630 makes it possible to perform a plasma oxidation process capable of reducing a plasma damage and controlling a film thickness in high precision to form a thin film.

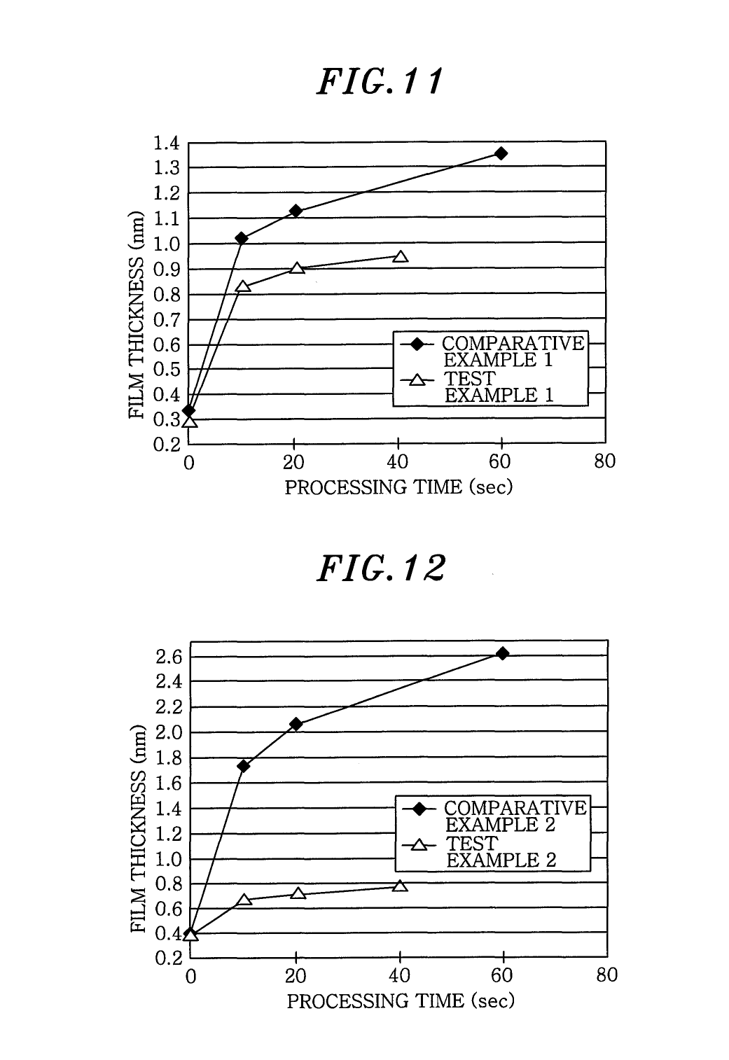

Hereinafter, the test results showing the effects of the present invention will be explained with reference to FIGS. 11 to 16.

### Test Example 1

A silicon oxide film was formed by oxidizing an Si substrate by the plasma oxidation apparatus 100 having the configuration shown in FIG. 1. In this example, the upper and the lower plate 61 and 62 of the dual plate structure 60 have the through holes 61a and 62a of which diameter is about 5 mm. Further, the upper and the lower plate 61 and 62 are made of quartz containing a small amount of impurities. Moreover, the upper and the lower plate 61 and 62 are spaced from each other by a distance of about 5 mm.

The plasma oxidation process was performed under following conditions:

Processing gas: Ar/O₂ (flow rate: 2000/200 mL/min(sccm))

Temperature of the wafer: 400° C.

Pressure: 266.6 Pa (2 Torr)

Power applied to plasma: 2.0 kW

Processing time: 10, 20, 40 and 60 seconds.

### Comparative Example 1

A silicon oxide film was formed by oxidizing an Si substrate under the same conditions used in Test example 1 by a plasma oxidation apparatus of which configuration is the same as that of the plasma oxidation apparatus 100 of FIG. 1 except that the dual plate structure 60 is not provided.

The film thicknesses of the silicon oxide films obtained in the test example 1 and Comparative example 1 were measured by an ellipsometer. A relationship between processing time and a film thickness is shown in FIG. 11.

Referring to FIG. 11, in Comparative example 1 having no dual plate structure 60, a silicon oxide film having a film thickness of about 1 mm was formed by performing the plasma oxidation process for 10 seconds. Further, the film thickness increased as the processing time increased. Meanwhile, in case of using the plasma oxidation apparatus 100 having the dual plate structure 60 shown in FIG. 1, the film thickness of the silicon oxide film formed did not exceed 1 nm even after the process has been performed for 40 seconds. Accordingly, it has been found that, the dual plate structure 60 is effective in controlling a film thickness of a thin film.

### Test Example 2

As in Test example 1, a silicon oxide film was formed by oxidizing an Si substrate with the use of the plasma oxidation apparatus 100 having the dual plate structure 60.

The plasma oxidation process was performed under following conditions:

Processing gas: Ar/O₂ (flow rate: 2000/20 mL/min(sccm))

Temperature of the wafer: 400° C.

Pressure: 66.7 Pa (500 mTorr)

Power applied to the plasma: 2.0 kW

Processing time: 10, 20, 40 and 60 seconds.

### Comparative Example 2

A silicon oxide film was formed by oxidizing an Si substrate under the same conditions used in the test example 2 by a plasma oxidation apparatus of which configuration is the same as that of the plasma oxidation apparatus 100 of FIG. 1 except that the dual plate structure 60 is not provided.

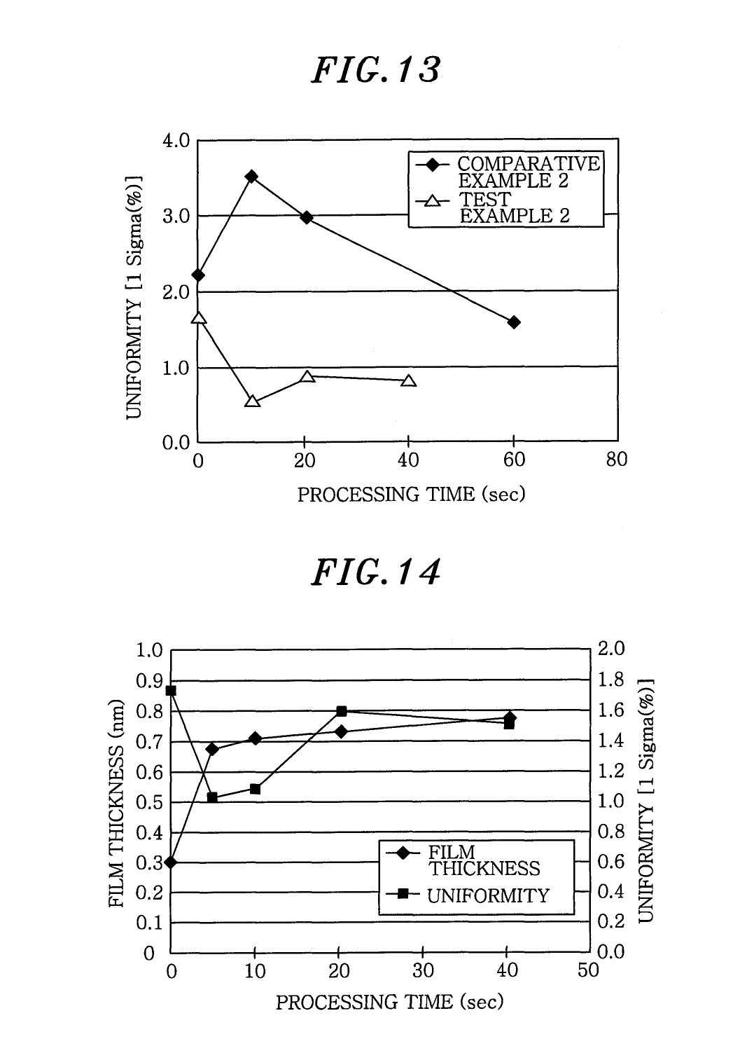

The film thicknesses of the silicon oxide films obtained in Test example 2 and Comparative example 2 were measured by an ellipsometer. A relationship between processing time and a film thickness is shown in FIG. 12. Moreover, a relationship between processing time and uniformity is illustrated in FIG. 13.

Referring to FIG. 12, in Comparative example 2 having no dual plate structure 60, a silicon oxide film having a film thickness of about 1.8 mm was formed by performing the plasma oxidation process for 10 seconds. Meanwhile, in the test example 2 in which the oxide film was formed by using the plasma oxidation apparatus 100 having the dual plate structure 60 of FIG. 1, the film thickness was about 0.8 nm even after the process has been performed for 40 seconds. Accordingly, it has been found that the dual plate structure 60 is effective in controlling a film thickness of a thin film.

Referring to FIG. 13, the uniformity of the film thickness was considerably higher in Test example 2 compared to Comparative example 2 having no dual plate structure 60.

### Test Example 3

As in Test example 1, a silicon oxide film was formed by oxidizing an Si substrate with the use of the plasma oxidation apparatus 100 having the dual plate structure 60. The plasma oxidation process was performed under following conditions:

Processing gas: Ar/O₂ (flow rate: 2000/5 mL/min(sccm))

Temperature of the wafer: 400° C.

Pressure: 66.7 Pa (500 mTorr)

Power applied to the plasma: 2.0 kW;

Processing time: 5, 10, 20 and 40 seconds.

The film thickness of the silicon oxide films thus obtained was measured by an ellipsometer. FIG. 14 shows relationships between processing time and uniformity, and between the processing time and a thickness of the oxide film.

As can be seen from FIG. 14, a thin film having a thickness of about 0.7 nm or less was formed by performing the process for 5 to 10 seconds by setting the ratio of O₂/Ar to 1/400. Under that condition, the film thickness could be controlled to be about 0.8 nm or less even when the process was performed for 40 seconds. Moreover, the oxide film thus formed has good uniformity in the film thickness.

### Test Examples 4 to 6 and Comparative Examples 3 and 4

As in Test example 1, a silicon oxide film was formed by oxidizing an Si substrate with the use of the plasma oxidation apparatus 100 having the dual plate structure 60. The plasma oxidation process was performed while using Ar and O₂ gases as processing gases. A flow rate ratio thereof and a processing pressure were as described below. For comparison, a silicon oxide film was formed by performing an oxidation process with the use of a plasma oxidation apparatus of which configuration is the same as that of the plasma oxidation apparatus of FIG. 1 except that the dual plate structure 60 is not provided. The following conditions apply to both the test examples and Comparative examples:

Temperature of the wafer: 400° C.

Power applied to the plasma: 2.0 kW

Processing time: 5 to 60 seconds.

The film thicknesses of the silicon oxide films thus obtained were measured by an ellipsometer.

### Test Example 4

### Using a Dual Plate Structure

Ar/O₂ ratio=400/1, Pressure=66.7 Pa (500 mTorr)

### Test Example 5

### Using a Dual Plate Structure

Ar/O₂ ratio=100/1, Pressure=66.7 Pa (500 mTorr)

### Test Example 6

### Using a Dual Plate Structure

Ar/O₂ ratio=10/1, Pressure=266.6 Pa (2 Torr)

### Comparative Example 3

### Using No Dual Plate Structure

Ar/O₂ ratio=10/1, Pressure=266.6 Pa (2 Torr)

### Comparative Example 4

### Using No Dual Plate Structure

Ar/O₂ ratio=100/1, Pressure=66.7 Pa (500 mTorr)

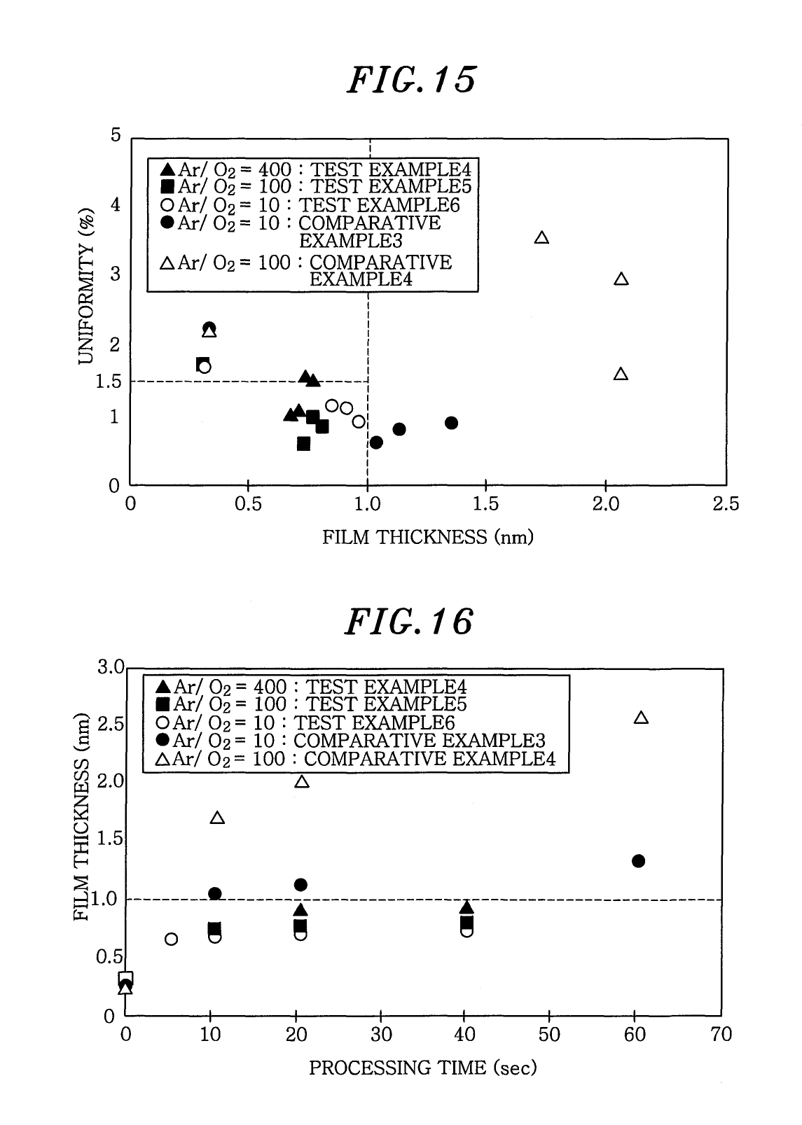

FIG. 15 shows a relationship between a film thickness of a silicon oxide film and uniformity thereof, and FIG. 16 describes a relationship between a processing time and the film thickness. Referring to FIG. 15, in the case of Test examples 4 to 6 using the plasma oxidation apparatus 100 having the dual plate structure 60, even when the silicon oxide film having a very thin film thickness ranging from about 0.5 to 1.0 nm was formed, the uniformity of the film thickness in the wafer surface was substantially about 1.5% or less and hardly affected by the gas flow rate ratio and the processing pressure. Moreover, as can be seen from FIG. 16, the film thickness did not exceed 1 nm even when the processing time was about 40 seconds. Accordingly, it has been that the presence of the dual plate structure 60 makes it easy to control a film thickness of a thin film. On the contrary, in the case of Comparative example 3 in which no dual plate structure 60 was used, the in-plane uniformity was relatively good, but the film thickness exceeded 1 nm. That is, the absence of the dual plate structure 60 makes it difficult to control a film thickness of a thin film. Besides, in the case of Comparative example 4 in which the dual plate structure 60 was not used, the film thickness exceeded 1.5 nm in a short period of time, and the uniformity was hardly controllable. From the above results, it has been found that the presence of the dual plate structure 60 makes it possible to form a silicon oxide film having an extremely thin film thickness ranging from about 0.5 to 1.0 nm while controlling the film thickness and the in-plane uniformity in high precision.

The present invention is not limited to the above embodiments but may be variously modified.

For example, although the RLSA plasma oxidation apparatus 100 has been exemplified in FIG. 1, the same effects as those of the RLSA plasma oxidation apparatus 100 can be obtained by providing a member having a labyrinth structure (the dual plate structure 60 or the like) in an apparatus for supplying a plasma to a target substrate in a specific direction. Therefore, there may be used a plasma oxidation apparatus of a remote plasma type, an ICP type, an ECR (Electron Cyclotron Resonance) type, a magnetron type, a surface reflected wave type or the like.

Further, although the microwave plasma processing apparatus for exciting a plasma by using a microwave having a frequency of 300 MHz to 300 GHz has been used in the first to the fourth embodiments, it is also possible to use a high frequency plasma processing apparatus for exciting a plasma by using a high frequency of 30 kHz to 300 MHz as the fifth and sixth embodiments.

The plasma oxidation apparatus has been described as an example in the above embodiments. However, the effect of reducing plasma damage by decreasing ions in the plasma by providing the dual plate structure 60 or the porous plate 63 or the effect of controlling a film thickness of a thin film can be also achieved by another process, e.g., a silicon nitriding process using as a processing gas a nitrogen-containing gas, other than the oxidation process. Accordingly, the plasma processing apparatus of the present invention can also be a plasma nitriding apparatus having the dual plate structure 60 or the porous plate 63.

Instead of the dual plate structure 60, there may be provided at least triple (or more) plate structure, if necessary.

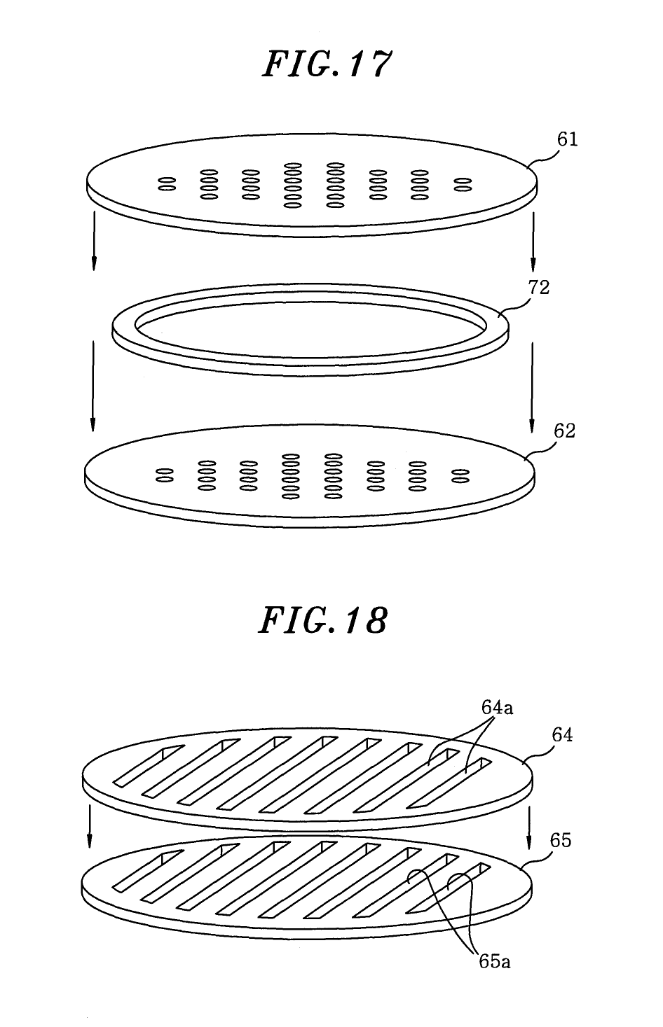

In the plasma oxidation apparatus 100 of FIG. 1, in order to support the upper and the lower plates 61 and 62 such that they are spaced apart from each other by a predetermined distance, so that the coupling members 71 are provided therebetween. However, instead of the coupling members 71, a circular ring-shaped gap ring 72 can be provided to adjust a distance between the upper and the lower plate 61 and 62, as shown in FIG. 17. Preferably, the gap ring 72 has a suitable to surround an arrangement area of the through holes 61a and 62a of the upper and the lower plate 61 and 62. By using the gap ring 72, the plasma can be prevented from being diffused in a horizontal direction in the space between the upper and the lower plate 61 and 62. As a result, it is possible to improve the controllability of trapping ions by the dual plate structure 60 while maintaining the processing efficiency by the plasma.

Moreover, the shape of the through holes 61a and 62a of the dual plate structure 60 is not limited to the circular shape but may be arbitrarily selected among, e.g., a square shape, an elongated slit shape or the like. For example, slits 64a and 65a can be respectively formed in the upper and the lower plate 64 and 65 in such a manner that the slits 64a and 65a are not overlapped with each other, as illustrated in FIG. 18.

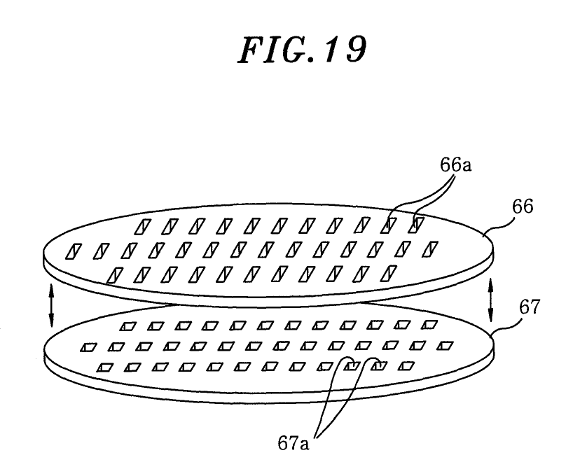

In addition, an upper plate 66 having a plurality of rectangular through holes 66a and a lower plate 67 having a plurality of rectangular through holes 67a can be arranged in an H pattern in such a manner that the through holes 66a and 67a are not overlapped with each other when seen from the top as depicted in FIG. 19.

Besides, an opening area or an opening ratio of the through holes 61a and 62a, the slits 64a and 65a and the like can be properly adjusted depending on the conditions of the plasma oxidation process or the like.

In FIGS. 5A to 5C, the formation of the gate insulating film of the gate electrode such as a MOS transistor or the like has been described as an example of the plasma processing by using the plasma oxidation apparatus 100 of the present invention. However, the plasma processing is not limited thereto but may be applied to, e.g., a nitriding process for forming a gate insulating film, a process for oxidizing polysilicon of a lower electrode of a capacitor, an oxidation process performed prior to formation of a high-k gate insulating film, a process for selectively oxidizing a polysilicon sidewall of a flash memory or the like.

The plasma processing apparatus and the plasma processing method of the present invention are suitably used in a manufacturing process of various semiconductor devices.

1: A plasma processing apparatus comprising:
a processing chamber for accommodating therein a target substrate;
a substrate supporting table for mounting thereon the target substrate in the processing chamber;
a plasma bending unit for allowing a plasma of a processing gas supplied from an upper portion of the processing chamber to flow along non-linear passageways toward the target substrate mounted on the substrate supporting table, the plasma bending unit including at least a first plate and a second plate each of which is made of a first dielectric material and has a plurality of through holes, wherein the first plate and the second plate are arranged such that the through holes of the respective plates are not overlapped with each other; and
a gap adjusting member provided between the first plate and the second plate for adjusting a gap between the first and second plates.

2-4. (canceled)

5: The plasma processing apparatus of claim 1, wherein the gap adjusting member is an annular member.

6: A plasma processing apparatus comprising:
a processing chamber for accommodating therein a target substrate;
a substrate supporting table for mounting thereon the target substrate in the processing chamber; and
a plasma bending unit for allowing a plasma of a processing gas supplied from an upper portion of the processing chamber to flow along non-linear passageways toward the target substrate mounted on the substrate supporting table, the plasma bending unit having a plate made of a porous dielectric material.

7: The plasma processing apparatus of claim 6, wherein the porous dielectric material has porosity ranging from about 70% to 80%.

8: The plasma processing apparatus of claim 6, further comprising a planar antenna having a plurality of slots for introducing a microwave into the processing chamber.

9: A plasma processing method for forming a silicon oxide film by performing an oxidation process for oxidizing silicon on a surface of a target substrate by using an oxygen-containing plasma in a processing chamber, wherein
the oxidation process is performed in a state that a plasma bending unit for allowing the oxygen-containing plasma to flow along non-linear passageways is provided between the target substrate and a plasma generation region in the processing chamber, the plasma bending unit including at least a first plate and a second plate each of which is made of a first dielectric material and has a plurality of through holes, wherein the first plate and the second plate are arranged such that the through holes of the respective first and second plates are not overlapped with each other.

10-11. (canceled)

12: A plasma processing method for forming a silicon oxide film by performing an oxidation process for oxidizing silicon on a surface of a target substrate by using an oxygen-containing plasma in a processing chamber, wherein
the oxidation process is performed in a state that a plasma bending unit for allowing the oxygen-containing plasma to flow along non-linear passageways is provided between the target substrate and a plasma generation region in the processing chamber, the plasma bending unit having a plate made of a porous dielectric material.

13: The plasma processing method of claim 12, wherein the porous dielectric material has porosity ranging from about 70% to 80%.

14: The plasma processing method of claim 9, wherein the silicon oxide film thus formed has a film thickness smaller than or equal to about 1 nm.

15: The plasma processing method of claim 9, wherein the oxygen-containing plasma is formed by introducing a microwave into the processing chamber with the use of a planar antenna having a plurality of slots.

16: The apparatus of claim 1, wherein the dielectric material is selected from quartz, SiN, SiC, Al₂O₃, and AlN.

17: The apparatus of claim 1, wherein the dielectric material is quartz material containing total impurities of about 50 ppm or less.

18: The apparatus of claim 1, wherein a distance between the second plate and the target substrate is in a range of from 3 to 20 mm.

19: The apparatus of claim 1, wherein each of the first and the second plate has a thickness ranging from 2 to 10 mm.

20: The apparatus of claim 1, wherein the plasma in a space provided between the second plate and the target substrate has an electron temperature controlled to be about 0.7 eV or less.

21: The apparatus of claim 20, wherein the plasma in the space provided between the second plate and the target substrate has an ion density controlled to be 1×10⁹ to 1×10¹¹/cm³.

22: The apparatus of claim 18, wherein the processing chamber has a second dielectric material provided at an upper portion thereof, and a distance between the second dielectric material and the first plate is in a range of from 20 to 50 mm.

23: The apparatus of claim 20, wherein an antenna is provided on the second dielectric material.

24: The apparatus of claim 23 wherein the antenna is a planar antenna having a plurality of slots and a microwave is supplied through the antenna into the processing chamber.

25: The apparatus of claim 1, wherein any one of an oxide film, a nitride film, and an oxynitride film is formed.

26: The apparatus of claim 25, wherein a thickness of the film formed is controlled to be 1 nm or less.
